(19) United States
(12) Patent Application Publication
(10) Pub. No.: US 2011/0256728 A1
(43) Pub. Date: Oct. 20, 2011

(54) WAFER THINNING METHOD IN WAFER TREATING SYSTEM

(75) Inventors: Toshio HIROE, Kyoto (JP); Kenichiro ARAI, Kyoto (JP)

(73) Assignee: Dainippon Screen Mfg. Co., Ltd.

(21) Appl. No.: 13/175,397

(22) Filed: Jul. 1, 2011

Related U.S. Application Data
(62) Division of application No. 11/750,620, filed on May 18, 2007, now abandoned.

(30) Foreign Application Priority Data
May 31, 2006 (JP) 2006-151490

(51) Int. Cl. H01L 21/306

(52) U.S. Cl. 438/745; 257/E21.219

(57) ABSTRACT

A wafer thinning apparatus for treating wafers each having at least a circuit-forming surface thereof protected, by immersing the wafers in a treating solution. The apparatus includes a support table for receiving, as placed thereon, containers each containing a plurality of wafers in one of groups into which the wafers are sorted according to predetermined ranges of thickness, a treating tank for storing the treating solution and receiving the containers, a transport mechanism for transporting the containers between the support table and the treating tank, and a control unit for controlling the transport mechanism to transport the containers successively to the treating tank, and for changing an immersion time of the containers in the treating tank for each group.

### CROSS REFERENCE TO RELATED APPLICATIONS

The present application is a divisional application of U.S. Ser. No. 11/750,620 filed May 18, 2007, which application claims benefit and priority of Japanese Application No. 2006-151490 filed May 31, 2006, which are incorporated herein in their entirety.

### BACKGROUND OF THE INVENTION

(1) Field of the Invention

This invention relates to a wafer thinning apparatus and a wafer treating system for chemically reducing the thickness of (i.e. thinning) wafers, such as of silicon semiconductor or compound semiconductor, with a treating solution.

(2) Description of the Related Art

What is predominant at present in conventional thinning treatment for reducing the thickness of wafers is mechanical polishing that mechanically grinds the back surface of each wafer using a whetstone. In this process, a temporary stop tape is applied as protective film to a circuit-forming surface of each wafer having a device formed thereon. The temporary stop tape is stripped off after the back surface of the wafer is ground by mechanical polishing. However, it is necessary to remove the temporary stop tape from the wafer after thinning treatment. There arise problems of yield falling due to damage of the wafers thinned and reduced in strength, and the wafers curving under the stress of mechanical polishing.

Thus, a proposal has been made to combine a technique of immersing a wafer in a treating solution such as caustic potash (KOH) solution to thin the wafer chemically by etching the back surface thereof (see Japanese Unexamined Patent Publication No. 2002-319578, for example), and a technique of immersing a plurality of wafers in a treating solution in a treating tank to treat the wafers as a batch (see Japanese Unexamined Patent Publication No. 2001-135710, for example). According to this proposed technique, the inconveniences noted above are eliminated since the back surface of each wafer is etched chemically. Further, the proposed technique can carry out thinning treatment at a very high level. Since a plurality of wafers are treated as a batch, the wafers are treated efficiently and are thinned uniformly with a very high degree of precision (e.g. at 1% or less of etching quantity).

However, the above conventional example has the following drawback.

In thinning treatment, what is required is not etching quantity, but accuracy of the resulting thickness and uniformity (little variation) of thickness among a plurality of wafers after the thinning treatment. However, since the proposed technique treats a plurality of wafers as a batch, variations in the thickness of wafers remain after the thinning treatment, to pose a problem of lacking in uniformity of finishing thickness.

Generally, remarkable variations (e.g. up to 10-odd micrometers) are found in the thickness of a plurality of wafers even in the same lot. Therefore, even if etching quantity is controlled accurately, variations in finishing thickness will remain with a plurality of wafers treated simultaneously.

### SUMMARY OF THE INVENTION

This invention has been made having regard to the state of the art noted above, and its object is to provide a wafer thing apparatus and a wafer treating system for performing thinning treatment by etching a plurality of wafers chemically with a treating solution, which can reduce variations in finishing thickness among the plurality of wafers.

The above object is fulfilled, according to this invention, by a wafer thinning apparatus for treating wafers each having at least a circuit-forming surface thereof protected, by immersing the wafers in a treating solution, comprising a support table for receiving, as placed thereon, containers each containing a plurality of wafers in one of groups into which the wafers are sorted according to predetermined ranges of thickness; a treating tank for storing the treating solution and receiving the containers; a transport mechanism for transporting the containers between the support table and the treating tank; and a control unit for controlling the transport mechanism to transport the containers successively to the treating tank, and for changing an immersion time of the containers in the treating tank for each group.

According to this invention, the control unit controls the transport mechanism to transport the containers successively from the support table to the treating tank, and to put the containers to the treatment by the treating solution. The control unit changes immersion time for each group. Since each cassette already stores only those of the wafers in a predetermined range of thickness, the plurality of wafers in that cassette have thickness variations falling within the predetermined range. Therefore, the thinning treatment performed by chemically etching the plurality of wafers can reduce variations in the finishing thickness of the wafers.

The apparatus may further comprise a computing unit for deriving the immersion time from a target thickness of the wafers, an average thickness in each group, and a treating rate by the treating solution.

The computing unit can derive an immersion time for the control unit to maintain each cassette in the treating solution, from a difference between a target thickness of the wafers ultimately remaining after the thinning treatment and an average thickness in each group, and the treating rate which is a thinning rate by the treating solution.

In another aspect of the invention, a wafer thinning apparatus for treating wafers each having at least a circuit-forming surface thereof protected, by immersing the wafers in a treating solution, comprises a support table for receiving, as placed thereon, containers each containing a plurality of wafers as rearranged in order of thickness; a treating tank for storing the treating solution and capable of receiving a plurality of wafers; a transport mechanism for transporting the wafers between the containers on the support table and the treating tank; and a control unit for controlling the transport mechanism to transport the wafers, in order of thickness from thickest to thinnest, from each container to the treating tank, to carry out treatment with the treating solution in the treating tank, and to withdraw all the wafers from the treating tank upon completion of the treatment.

According to this invention, the control unit controls the transport mechanism to transport the wafers, in order of thickness from thickest to thinnest, from each container on the support table to the treating tank, to subject each wafer to the treatment by the treating solution, and to withdraw all the wafers upon completion of the treatment. The thicknesses of the plurality of wafers are measured beforehand, and stored in the container in order of thickness. The wafers are immersed in the treating solution, successively, starting with the thickest wafer, thereby changing the immersion time for each wafer. This procedure can absorb the variations in thickness among the plurality of wafers. Therefore, the thinning treatment with the treating solution chemically etching the plurality of wafers can provide reduced variations in finishing thickness of the plurality of wafers.

The control unit may be arranged to change time intervals for transporting the wafers according to differences in thickness between adjoining wafers.

By changing a time interval for transporting a next wafer according to a difference in thickness to a preceding wafer, the difference in thickness between the wafers can be absorbed.

In a further aspect of the invention, a wafer treating system for treating wafers with a treating solution is provided, which comprises a grouping apparatus including a measuring device for measuring thickness of the wafers, and a storing device for grouping a plurality of wafers according to predetermined ranges of thickness based on results of measurement by the measuring device, and storing a plurality of wafers in each group into one container; an edge holding jig attaching apparatus for attaching an edge holding jig to each of wafers to be treated, which have been grouped by the grouping apparatus, for protecting portions of the wafer from the treating solution, the portions including an entire area of the circuit-forming surface, a peripheral surface of the wafer, and a peripheral area of a predetermined width inward from the peripheral surface toward a center of a surface to be treated which is reverse of the circuit-forming surface, and excluding a central area in a circle to be treated; and a wafer thinning apparatus including a support table for receiving, as placed thereon, containers containing the wafers each having the edge holding jig attached thereto by the edge holding jig attaching apparatus, a treating tank for storing the treating solution and receiving the containers, a transport mechanism for transporting the containers between the support table and the treating tank, and a control unit for controlling the transport mechanism to transport the containers successively to the treating tank, and for changing an immersion time of the containers in the treating tank for each group.

According to the invention, the measuring device of the grouping apparatus measures the thickness of each wafer, and the storing unit stores only the wafers in the same group in the same container beforehand. After the edge holding jig attaching apparatus attaches an edge holding jig to each wafer, the control unit of the wafer thinning apparatus controls the transport mechanism to transport one container after another from the support table to the treating tank, and to put the containers to the treatment by the treating solution. The control unit changes immersion time for each group. Since each cassette already stores only those of the wafers in a predetermined range of thickness, the plurality of wafers in that cassette have thickness variations falling within the predetermined range. Therefore, the thinning treatment performed by chemically etching the plurality of wafers can reduce variations in the finishing thickness of the wafers.

In a still further aspect of the invention, a wafer treating system for treating wafers with a treating solution is provided, which comprises a rearranging apparatus including a measuring device for measuring thickness of the wafers, and a storing device for rearranging the wafers in order of thickness based on results of measurement by the measuring device, and storing the wafers as rearranged into containers; an edge holding jig attaching apparatus for attaching an edge holding jig to each of wafers to be treated, which have been rearranged by the rearranging apparatus, for protecting portions of the wafer from the treating solution, the portions including an entire area of the circuit-forming surface, a peripheral surface of the wafer, and a peripheral area of a predetermined width inward from the peripheral surface toward a center of a surface to be treated which is reverse of the circuit-forming surface, and excluding a central area in a circle to be treated; and a wafer thinning apparatus including a support table for receiving, as placed thereon, containers containing the wafers each having the edge holding jig attached thereto by the edge holding jig attaching apparatus, a treating tank for storing the treating solution and capable of receiving a plurality of wafers, a transport mechanism for transporting the wafers between the support table and the treating tank, and a control unit for controlling the transport mechanism to transport the wafers, in order of thickness from thickest to thinnest, from each container to the treating tank, to carry out treatment with the treating solution in the treating tank, and to withdraw all the wafers from the treating tank upon completion of the treatment.

According to the invention, the measuring device of the rearranging apparatus measures the thicknesses of a plurality of wafers, and the storing unit stores the wafers in the order of thickness in a container. After the edge holding jig attaching apparatus attaches an edge holding jig to each wafer, the control unit of the wafer thinning apparatus controls the transport mechanism to transport the wafers from the container on the support table to the treating tank, in the order of thickness from thickest to thinnest, to subject each wafer to the treatment by the treating solution, and to withdraw all the wafers upon completion of the treatment. The thicknesses of the plurality of wafers are measured beforehand, and stored in the container in the order of thickness. The wafers are immersed in the treating solution, successively, starting with the thickest wafer, thereby changing the immersion time for each wafer. This procedure can absorb the variations in thickness among the plurality of wafers. Therefore, the thinning treatment with the treating solution chemically etching the plurality of wafers can provide reduced variations in finishing thickness of the plurality of wafers.

### BRIEF DESCRIPTION OF THE DRAWINGS

For the purpose of illustrating the invention, there are shown in the drawings several forms which are presently preferred, it being understood, however, that the invention is not limited to the precise arrangement and instrumentalities shown.

FIG. 1 is a view showing an outline procedure of wafer treatment in Embodiment 1;

FIG. 2 is a schematic view showing an outline construction of a wafer treating system;

FIG. 3 is a view showing an outline construction of a grouping apparatus;

FIG. 4 is a perspective view showing an edge protection jig;

FIG. 5 is a plan view showing an outline construction of an edge protection jig attaching and detaching apparatus;

FIG. 6 is a plan view showing an outline construction of a wafer thinning apparatus;

FIG. 7 is a block diagram showing a control system of the wafer thinning apparatus;

FIG. 8 is a view showing an outline procedure of wafer treatment in Embodiment 2;

FIG. 9 is a plan view showing an outline construction of a wafer thinning apparatus; and

FIG. 10 is a block diagram showing a control system of the wafer thinning apparatus.

### DESCRIPTION OF THE PREFERRED EMBODIMENTS

### Embodiment 1

Embodiment 1 of this invention will be described hereinafter with reference to the drawings.

<Outline of Treatment>

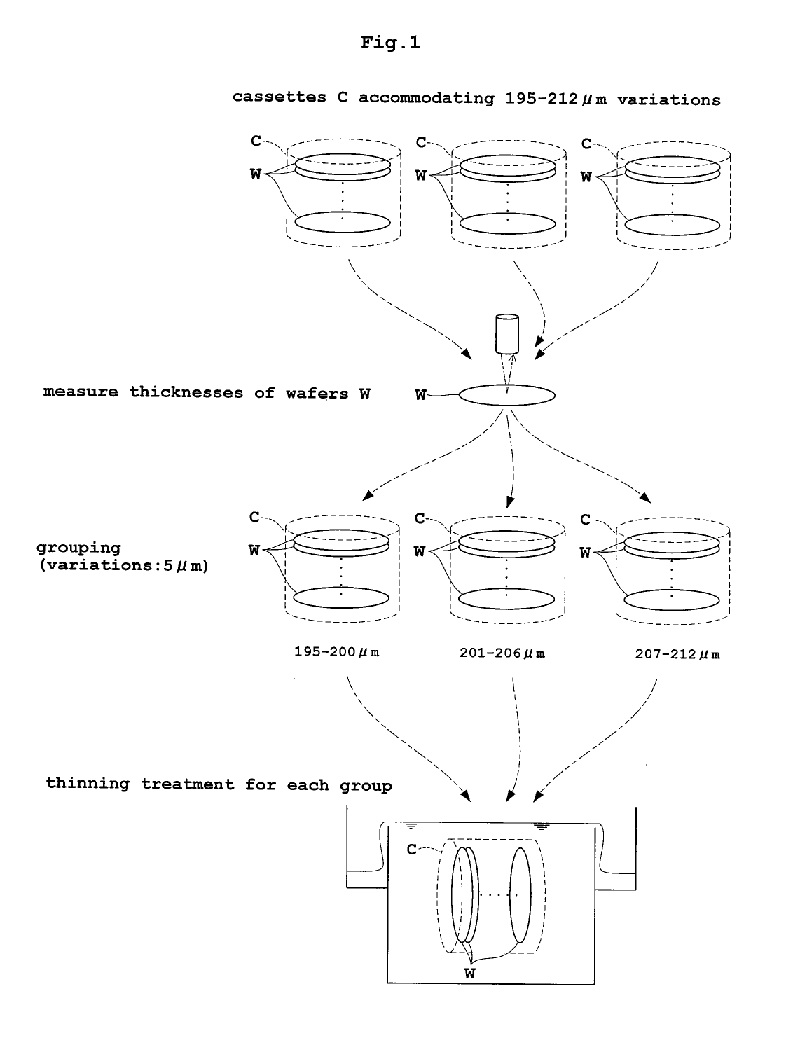

First, an outline of this embodiment will be described with reference to FIG. 1. FIG. 1 is a view showing an outline procedure of wafer treatment in Embodiment 1.

Assume that a plurality of wafers W to be treated have varied thicknesses in the range of 195 μm to 212 μm, and that a predetermined number (e.g. 50) of such wafers W are stored in each cassette C. That is, the variation in the thickness of all the wafers W at this stage is 17 μm.

First, the wafers W are successively taken out of each cassette C, and their thicknesses are measured. The wafers W are sorted into groups according to predetermined ranges of thickness. A plurality of wafers W in each group are stored in the same cassette C. The predetermined ranges are 195-200 μm, 201-206 μm and 207-212 μm, for example, each covering a 5 μm variation in thickness.

Each cassette C storing the wafers W grouped as described above is immersed for treatment in a treating solution such as of caustic potash (KOH), for example. The time of immersion in the treating solution is varied for each cassette C. Assume, for example, that the first cassette C stores wafers W having thicknesses in the predetermined range of 105-200 μm, the second cassette C stores wafers W having thicknesses in the predetermined range of 201-206 μm, and the third cassette C stores wafers W having thicknesses in the predetermined range of 207-212 μm. In this case, immersion times may be set based on a “target thickness” which is a thickness of wafers W resulting from the thinning treatment, an “average thickness” within each group, and a “treating rate” of the treating solution. For example, the first cassette C contains wafers W having an average thickness of 197.5 μm, the second cassette C wafers W having an average thickness of 203.5 μm, and the third cassette C wafers W having an average thickness of 209.5 μm. Provided that the target thickness and treating rate are unvaried, a longer immersion time is set for the third cassette C than for the first cassette C.

Thus, each cassette C stores only those wafers W having thicknesses in a predetermined range among the plurality of wafers W. The variations in the thickness of the plurality of wafers W in each cassette C fall within the predetermined range of 5 μm. Therefore, the thinning treatment with the treating solution chemically etching the plurality of wafers W can provide reduced variations in finishing thickness of the plurality of wafers W.

<Wafer Treating System>

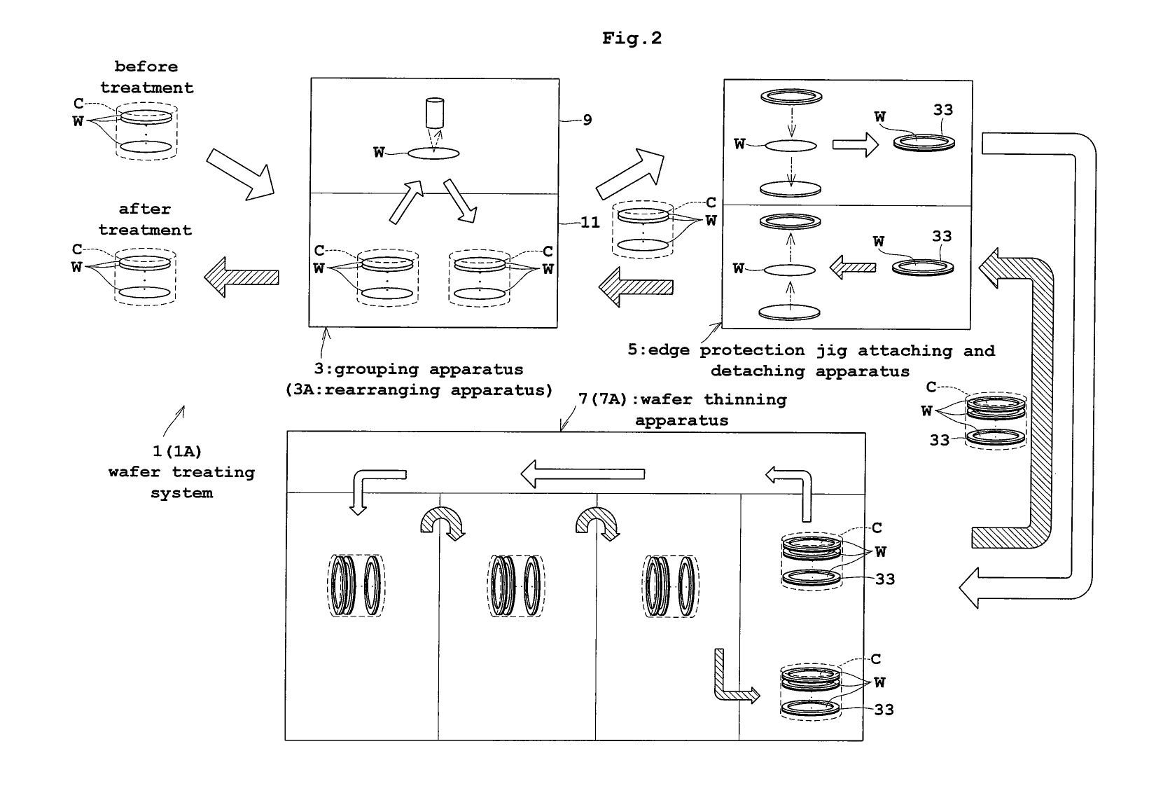

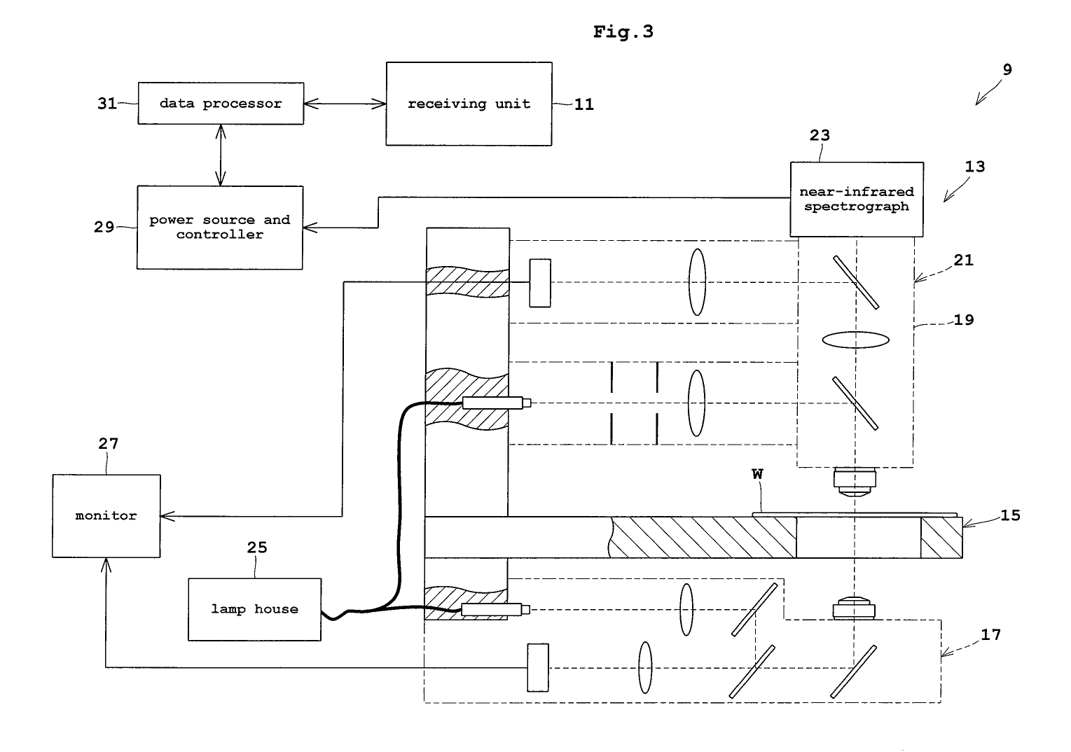

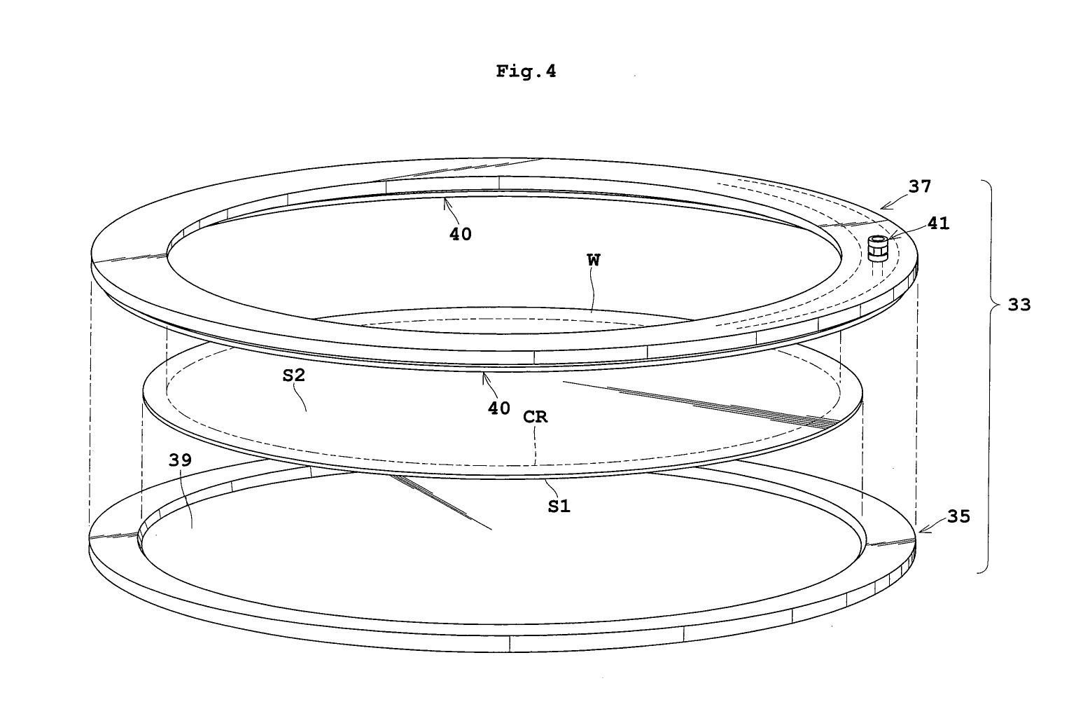

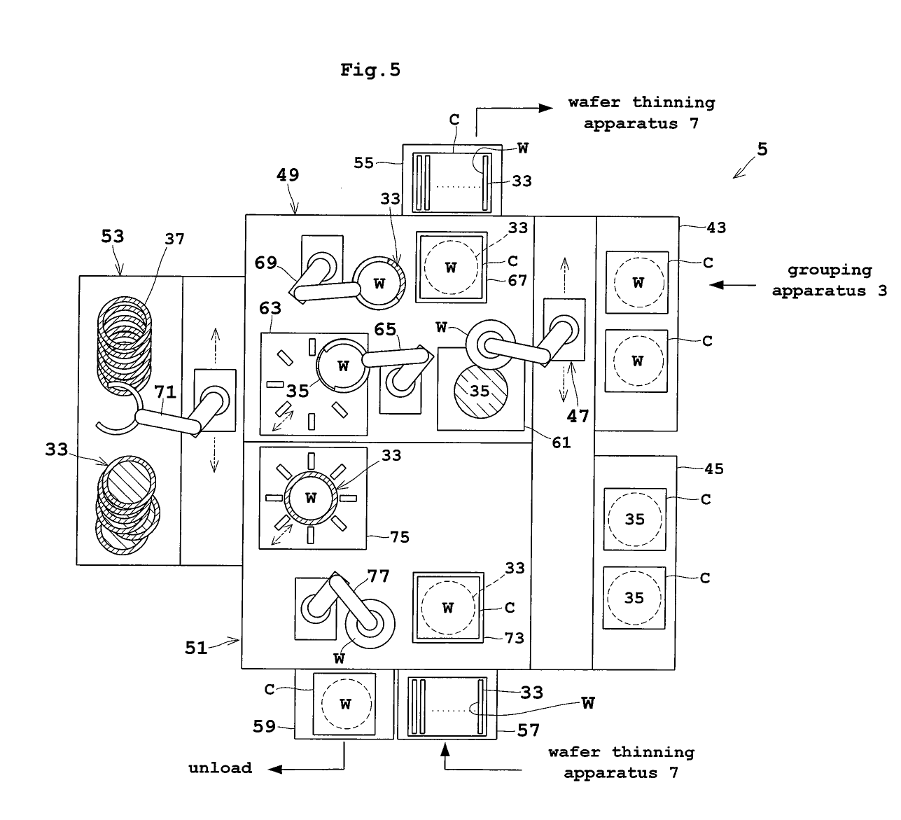

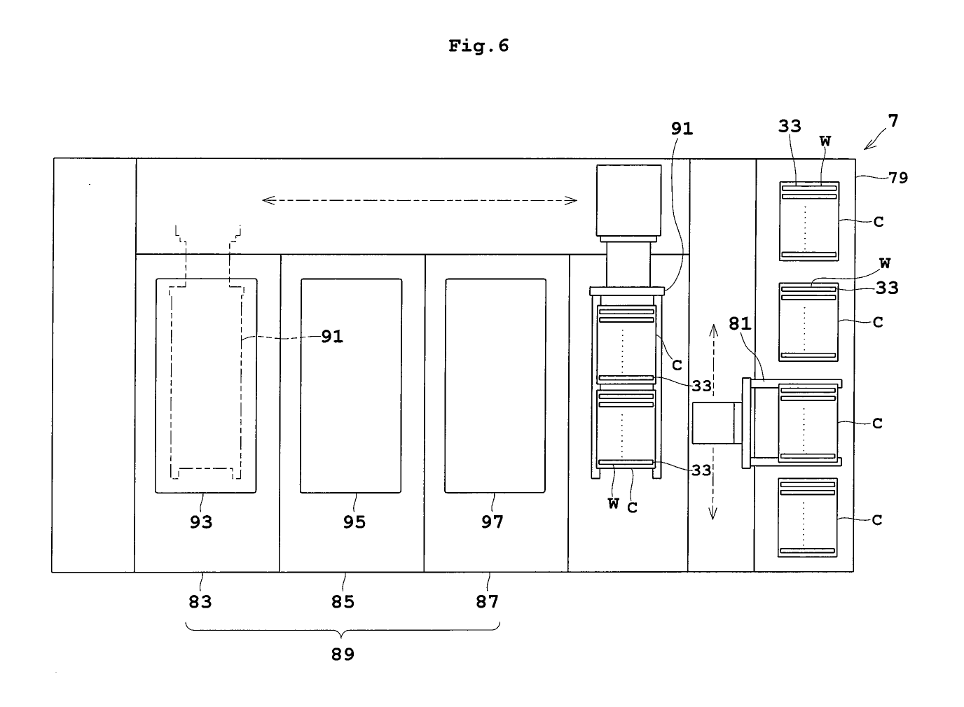

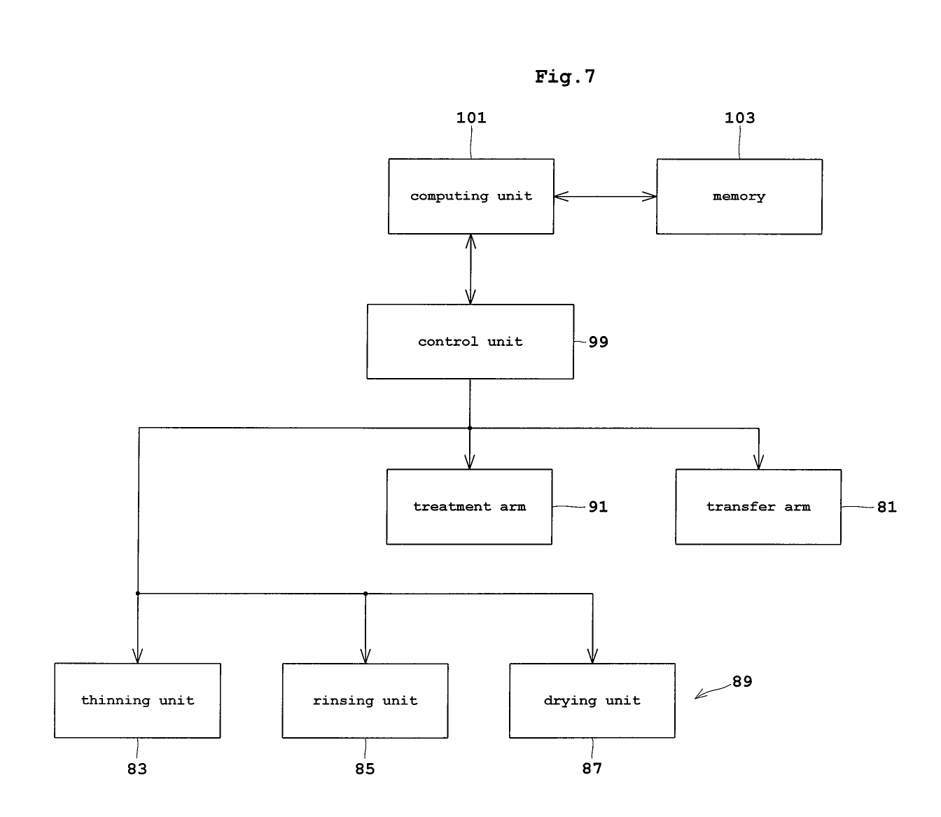

Next, a specific wafer treating system for performing the above treatment will be described with reference to FIGS. 2 through 6. FIG. 2 is a schematic view showing an outline construction of the wafer treating system. FIG. 3 is a view showing an outline construction of a grouping apparatus. FIG. 4 is a perspective view showing an edge protection jig. FIG. 5 is a plan view showing an outline construction of an edge protection jig attaching and detaching apparatus. FIG. 6 is a plan view showing an outline construction of a wafer thinning apparatus. FIG. 7 is a block diagram showing a control system of the wafer thinning apparatus.

As shown in FIG. 2, this wafer treating system 1 includes a grouping apparatus 3, an edge protection jig attaching and detaching apparatus 5 and a wafer thinning apparatus 7.

The grouping apparatus 3 has a thickness measuring unit 9 and a storing unit 11.

The storing unit 11 receives, as placed thereon, cassettes C containing wafers W before the thinning treatment and after the thinning treatment. In the case of a cassette C containing wafers W before the thinning treatment, each wafer W is taken out and transported to the thickness measuring unit 9 where the thickness of wafer W is measured. According to the thickness, the wafer W is stored in a different cassette C corresponding to a group of thicknesses in a predetermined range. In this way, a plurality of wafers W are grouped according to thickness. In the case of a cassette C containing wafers W after the thinning treatment, each wafer W is taken out and transported to the thickness measuring unit 9 where the thickness of thinned wafer W is measured. A difference to the target thickness is collected as data.

The thickness measuring unit 9 corresponds to the measuring device in this invention. The storing unit 11 corresponds to the storing device in this invention.

As shown in FIG. 3, the thickness measuring unit 9 includes an optical thickness measuring device 13. The optical thickness measuring device 13 has a function to determine the thickness of each wafer W based on the intensity of near-infrared light transmitted through the wafer W. Specifically, the measuring device 13 includes a stage 15 on which each wafer W is placed, a visible light microscope 17 disposed below the stage 15 for irradiating the wafer W with visible light from below, and determining an irradiating position of the visible light (thickness measuring position) on the lower surface of wafer W, an incident-light microscope 21 disposed on a side of a body tube 19 erected above the stage 15 for irradiating the wafer W with visible light from above, and determining an irradiating position of the visible light (thickness estimating position) on the upper surface of wafer W, and a near-infrared spectrograph 23 mounted on the body tube 19 for extracting only the near infrared region from the light transmitted through the wafer W.

A lamp house 25 for generating visible light is connected through optical fibers to the visible microscope 17 and incident-light microscope 21 of the optical thickness measuring device 13. Further, a monitor 27 is connected for displaying stereoscopic images from a camera of each of the visible microscope 17 and incident-light microscope 21. A power source and controller 29 has functions to supply electric power and control the optical thickness measuring device 13, and receive near-infrared light intensity signals from the near-infrared spectrograph 23. A data processor 31 is connected to the power source and controller 29. When the wafer W has not undergone the thinning treatment yet, the data processor 31 derives the thickness of wafer W from the near-infrared light intensity and, based on the thickness, instructs the storing unit 11 in which cassette C the wafer W should be stored. When the wafer W has undergone the thinning treatment, the data processor 31 obtains the thickness of wafer W, stores it as finishing thickness, and determines the quality of treatment based on a difference to the target thickness.

An edge protection jig 33 as shown in FIG. 4, for example, is attached to the wafer W after measurement of its thickness. The edge protection jig 33 corresponds to the edge holding jig in this invention.

This edge protection jig 33 covers the entire area of a circuit-forming surface S1 of the wafer W, the peripheral surface thereof, and a reverse surface S2 of the wafer W excluding a central area in a circle CR to be treated. That is, the jig 33 covers the reverse surface S2 of the wafer W to the extent of a predetermined width from the peripheral surface toward the center. The jig 33 serves to keep the covered portions of the wafer W out of contact with the treating solution.

Specifically, the jig 33 includes a base member 35 slightly larger in diameter than the wafer W, and a seal ring 37 placed from above the base member 35 to hold the wafer W in between. The base member 35 has a shallow recess 39 formed centrally thereof to fit the outer shape of the wafer W and correspond to the thickness of the wafer W. The wafer W is placed in the shallow recess 39 with the circuit-forming surface S1 facing the bottom of the recess 39. The seal ring 37 has a lip packing 40 disposed on the lower surface thereof to mark the treatment circle CR to be exposed to the treating solution on the surface S2 to be treated. Further, the seal ring 37 has a valve 41 disposed in a position on the upper surface thereof and communicating with a decompression space in the lip packing 40. The valve 41 includes a check valve and a vacuum breaker, and communicates with a suction device not shown. The valve 41 can maintain the decompression space in the lip packing 40 at negative pressure after suction is canceled. Consequently, only by placing the wafer W in the base member 35, placing the seal ring 37 from above, and causing the suction device to take sucking action, the seal ring 37 is held tight with the base member 35 after the suction is canceled. After thinning treatment of the wafer W is completed, the vacuum breaker of the valve 41 is operated to cancel the negative pressure of the decompression space in the lip packing 40. Then, the seal ring 37 can be released from the base member 35.

The “lip packing” refers to the type of packing in which, when a fluid is pressurized, a pressure greater than the fluid pressure acts on the lip tip of the packing to make pressure contact with a surface, and the pressure contact is maintained by self-sealing action. Such lip packing includes U-packing, V-packing, L-packing and J-packing, which are also called dust seals or scrapers.

An edge protection jig attaching and detaching apparatus 5 shown in FIG. 5 automatically attaches the edge protection jig 33 described above to each of the plurality of wafers W grouped by the grouping apparatus 3, and automatically detaches the jig 33 from each wafer W after the thinning treatment.

The edge protection jig attaching and detaching apparatus 5, which corresponds to the edge holding jig attaching apparatus and edge holding jig detaching apparatus in this invention, includes a support table 43 for receiving, as placed thereon, cassettes C storing wafers W to undergo the thinning treatment, a support table 45 for receiving, as placed thereon, cassettes C storing only the base members 35 of edge protection jigs 33, a first transport arm 47 movable along the tables 43 and 45, an attaching unit 49 for attaching the edge protection jigs 33 to the wafers W, a detaching unit 51 disposed adjacent the attaching unit 49 for detaching the edge protection jigs 33 from the wafers W after the thinning treatment, and a storage unit 53 disposed adjacent the attaching unit 49 and detaching unit 51 and having a region for storing only the seal rings 47 and a region for storing the edge protection jigs 33.

A support table 55 is disposed adjacent the attaching unit 49 for receiving a cassette C storing wafers W with edge protection jigs 33 attached thereto. This cassette C is transported to the wafer thinning apparatus 7.

A support table 57 is disposed adjacent the detaching unit 51 for receiving a cassette C storing wafers W (with edge protection jigs 33 attached thereto) after the thinning treatment. This cassette C is transported from the wafer thinning apparatus 7. A support table 59 is disposed adjacent the support table 57 for receiving a cassette C storing wafers W after edge protection jigs 33 are detached therefrom.

The attaching unit 49 noted above includes a stacking table 61 for receiving a base member 35 transported from a cassette C on the support table 45 by the first transport arm 47, and allowing a wafer W transported from a cassette C on the support table 43 by the first transport arm 47 to be placed on the base member 35. A joining table 63 is disposed adjacent the storage unit 53 as seen from the stacking table 61. The joining table 63 receives the base member 35 with the wafer W placed thereon, horizontally adjusts a seal ring 37 placed on the wafer W, and allows the wafer W and edge protection jig 33 to be integrated by suction through the valve 41 (FIG. 4) of the seal ring 37. A second transport arm 65 is disposed between the stacking table 61 and joining table 63 for transporting the base member 35 and wafer W from the stacking table 61 to the joining table 63. A temporary store 67 is disposed between the stacking table 61 and support table 55. The temporary store 67 receives a cassette C with its storage rack placed in a horizontal position. The cassette C in the temporary store 67 receives wafers W (with edge protection jigs 33) transported from the joining table 63 by a third transport arm 69 disposed adjacent the joining table 63. When the cassette C in the temporary store 67 is filled with wafers W (with edge protection jigs 33), the cassette C is turned from the horizontal position to a vertical position, and transferred to the support table 55.

The seal rings 37 in the storage unit 53 are transported to the joining table 63 by a fourth transport arm 71 disposed adjacent the attaching unit 49 and detaching unit 51. The storage unit 53 also receives seal rings 37 and base members 35 (edge protection jigs 33) detached from wafers W in the detaching unit 51, and transported by the fourth transport arm 71.

The detaching unit 51 includes a temporary support 73 disposed adjacent the support table 57. A cassette C storing wafers W after the thinning treatment (with edge protection jigs 33) is placed on the support table 57, and is transferred to the temporary support 73 as turned from the vertical position to the horizontal position. The detaching unit 51 includes a separating table 75 disposed adjacent the storage unit 53 and attaching unit 49. The separating table 75 cancels the negative pressure in the lip packing 40 through the valve 41 of the seal ring 37 attached to each wafer W to render the seal ring 37 releasable from the base member 35 and wafer W. A fifth transport arm 77 is disposed between the separating table 75 and support table 59. The fifth transport arm 77 takes wafers W (with edge protection jigs 33) out of the cassette C on the temporary table 73, and transports the wafers W to the separating table 75. After each seal ring 37 separated on the separating table 75 is transported to the storage unit 53 by the fourth transport arm 71, the fifth transport arm 77 transports only the wafer W to a cassette C on the support table 59. The base member 35 left on the separating table 75 is transported to the storage unit 53 by the fourth transport arm 71.

Next, the wafer thinning apparatus 7 will be described with reference to FIG. 6.

The wafer thinning apparatus 7 includes a support table 79 for receiving, as placed thereon, cassettes C each storing a plurality of wafers W in the same one of groups formed for the predetermined ranges of thickness, with edge protection jigs 33 attached by the edge protection jig attaching and detaching apparatus 5, a transfer arm 81 movable along the support table 79 for transferring the cassettes C, a treating station 89 having a thinning unit 83, a rinsing unit 85 and a drying unit 87 arranged in order from the end remote from the transfer arm 81, and a treatment arm 91 movable along the treating station 89 for transferring cassettes C to and from the transfer arm 81, and moving the cassettes C to and from each of the treating units 83, 85 and 87. The treatment arm 91 is constructed to hold two cassettes C in a series arrangement, which cassettes C store wafers W in the same group. The treatment arm 91 may have a construction for holding one cassette C at a time.

The transfer arm 81 and treatment arm 91 correspond to the transport mechanism in this invention.

The thinning unit 83 has a treating tank 93 that can accommodate two cassettes C, and stores a caustic potash (KOH) solution as a treating solution heated to high temperature, for example. The treatment arm 91 immerses the cassettes C in the solution. Immersion time is changed for each group of wafers W stored in the cassettes C. The rinsing unit 85 has a rinsing tank 95 storing heated deionized water for cleaning the wafers W withdrawn from the treating tank 93. The drying unit 87 has a drying chamber 97 for drying and removing droplets from the wafers W cleaned with the deionized water. The treated wafers W are returned as stored in the cassettes C to the support table 79 by the transfer arm 81.

The above wafer thinning apparatus 7 has a control system constructed as shown in FIG. 7.

A control unit 99 performs an overall control of the transfer arm 81, treatment arm 91 and treating station 89. The control items include, for example, timing of movement of the transfer arm 81 and treatment arm 91, and the time of immersion in the treating tank 93 by the treatment arm 91. The immersion time is determined by a computing unit 101. The computing unit 101 is connected to a memory 103 storing treatment information including a “target thickness”, “average thicknesses of the groups” and an “etching rate” which is a treating rate of the treating solution. The computing unit 101 determines an immersion time from this information, and transmits the immersion time to the control unit 99.

According to the foregoing wafer treating system 1, the thickness measuring unit 9 of the grouping apparatus 3 measures the thickness of each wafer W, and the storing unit 11 stores only the wafers W in the same group in the same cassette C beforehand. After the edge protection jig attaching and detaching apparatus 5 attaches an edge protection jig 33 to each wafer W, the control unit 99 of the wafer thinning apparatus 7 operates the transfer arm 81 and treatment arm 91 to transport one cassette C after another from the support table 79 to the treating tank 93. In subjecting each cassette C to the treatment by the treating solution, the control unit 99 changes the immersion time for each group. Since each cassette C already stores only those of the wafers W in a predetermined range of thickness, the plurality of wafers W in that cassette C have thickness variations falling within the predetermined range. Therefore, the thinning treatment performed by chemically etching the plurality of wafers W can reduce variations in the finishing thickness of the wafers W. Subsequently, the edge protection jig attaching and detaching apparatus 5 releases the edge protection jig 33 from each wafer W. It is thus possible to thin only the part within the treatment circle of each wafer W, leaving the predetermined width of the treatment surface intact. The strength of wafers W is maintained after the thinning treatment. As a result, the wafers W can be handled with ease after the thinning treatment.

Further, the thickness measuring unit 9 of the grouping apparatus 3 measures the post-treatment thicknesses of wafers W, and collects their differences to the target thickness as data. The quality of the treatment is determined based on the differences to the target thickness. Thus, propriety of the treatment can be determined easily.

### Embodiment 2

Next, Embodiment 2 of this invention will be described with reference to the drawings.

<Outline of Treatment>

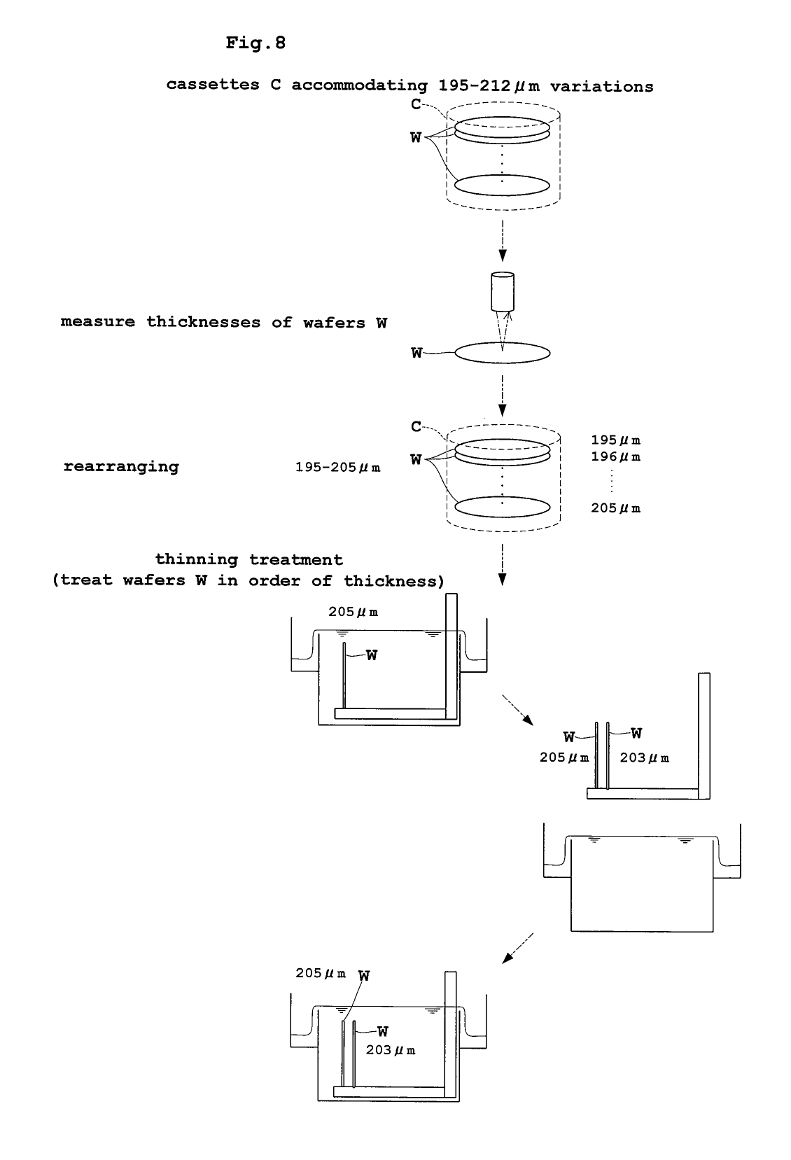

First, an outline of this embodiment will be described with reference to FIG. 8. FIG. 8 is a view showing an outline procedure of wafer treatment in Embodiment 1.

Assume that, as in Embodiment 1 described above, a plurality of wafers W to be treated have varied thicknesses in the range of 195 μm to 212 μm. That is, the variation in the thickness of all the wafers W at this stage is 17 μm.

First, the wafers W are successively taken out of each cassette C, and their thicknesses are measured. Then, the wafers W are rearranged in order of thickness. The order of thickness here refers to an order of increasing thickness or decreasing thickness. In this embodiment, the wafers W are stored in the cassette C in the order of decreasing thickness, i.e. from thickest to thinnest.

The plurality of wafers W rearranged in order of thickness as described above and stored in each cassette C are taken out of the cassette C in the order of decreasing thickness, and are immersed in that order in the treating solution such as of caustic potash (KOH) for treatment. Assume, for example, that the thickest wafer W is 205 μm thick, the next thickest 203 μm thick, and the third thickest 200 μm thick. Only the wafer W 205 μm thick is first placed on the treatment arm and immersed in the treating solution. Upon lapse of a time corresponding to a difference to the 203 μm thickness of the next wafer W, the treatment arm is pulled up from the treating solution. Then, the wafer W 203 μm thick is placed on the treatment arm, and the two wafers W are immersed in the treating solution. After a time corresponding to a difference in thickness to the next wafer W, the next wafer W is added again as described above. Finally, the treatment arm and all the wafers W are pulled up from the treating solution upon lapse of a treatment completion time derived from the thickness of the wafer W first put to the treatment, the target thickness, and the treating rate of the treating solution.

As described above, the wafers W in each cassette C are immersed in the treating solution, successively in order of thickness, the thickest wafer W first to the thinnest wafer W, and the thinning treatment is carried out by the treating solution for the respective wafers W. All the wafers W are withdrawn upon completion of the treatment. The thicknesses of the plurality of wafers W are measured beforehand, and stored in the cassette C in order of thickness. The wafers W are immersed in the treating solution, successively, starting with the thickest wafer W, thereby changing the immersion time for each wafer W. This procedure can absorb the variations in thickness among the plurality of wafers W. Therefore, the thinning treatment with the treating solution chemically etching the plurality of wafers W can provide reduced variations in finishing thickness of the plurality of wafers W.

<Wafer Treating System>

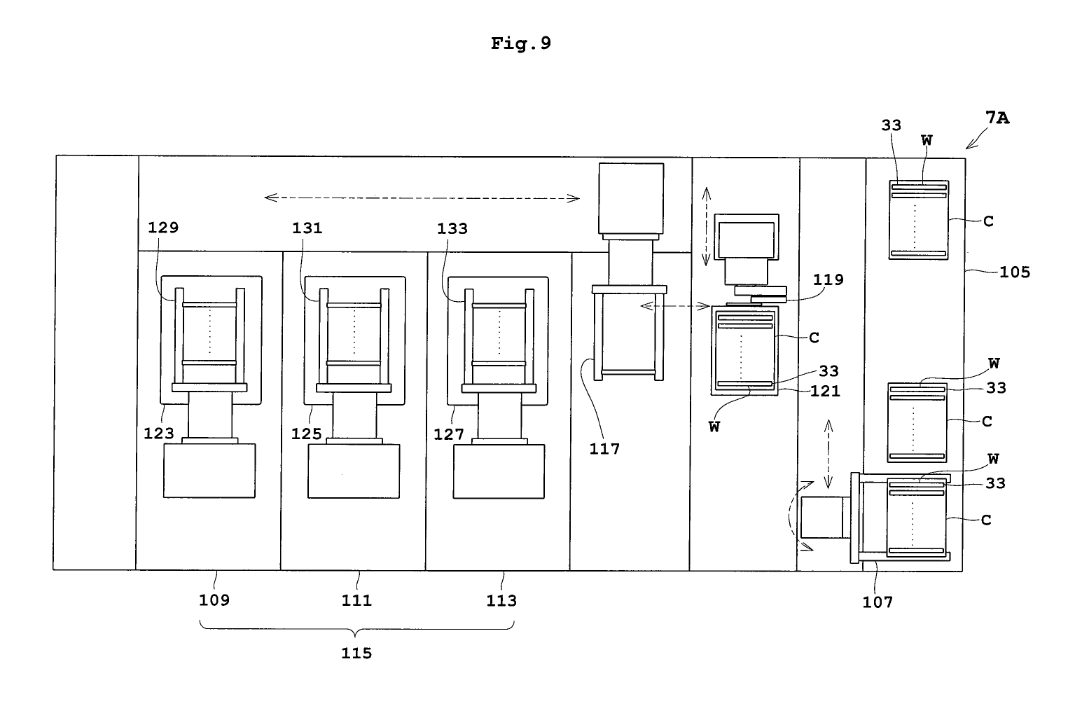

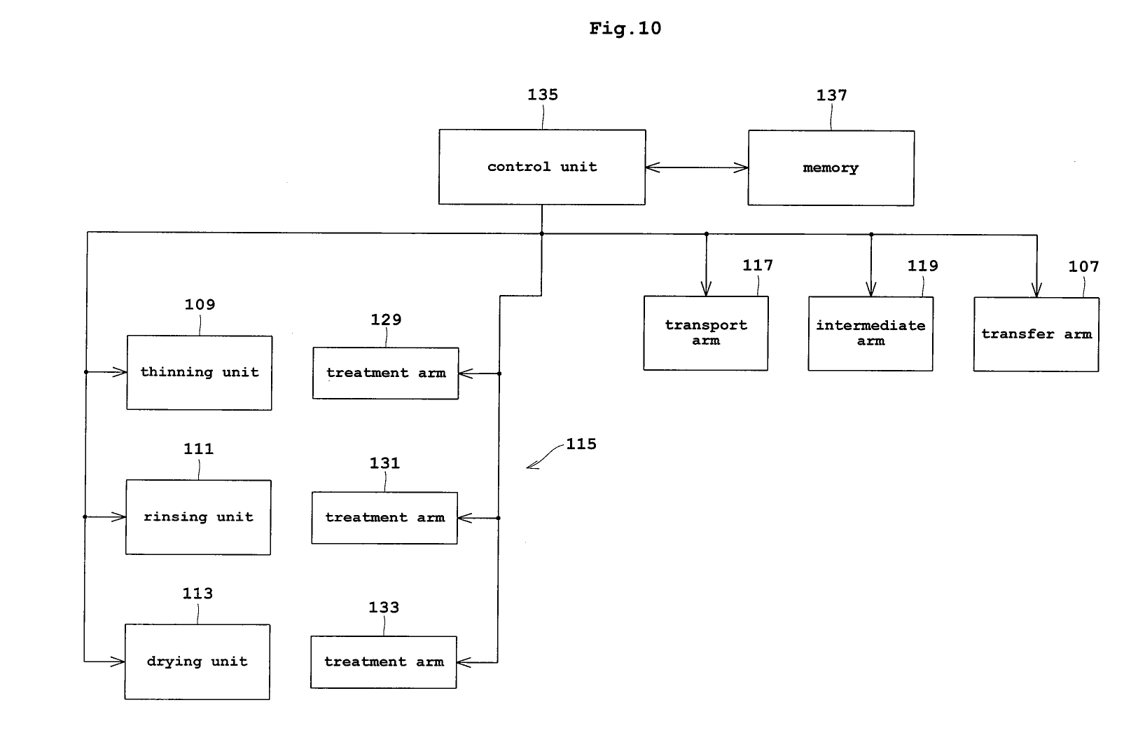

Next, a specific wafer treating system for performing the above treatment will be described with reference to FIGS. 9 and 10. FIG. 9 is a plan view showing an outline construction of a wafer thinning apparatus. FIG. 10 is a block diagram showing a control system of the wafer thinning apparatus.

First, an outline construction of a wafer treating system 1A will be described. The outline construction of the wafer treating system 1A itself is the same as the wafer treating system 1 in Embodiment 1, and will therefore be described with reference to FIG. 2.

The wafer treating system 1A includes a rearranging apparatus 3A in place of the grouping apparatus 3 of the wafer treating system 1 (see FIG. 2). The construction itself is the same as in FIG. 2, and the difference lies in that the data processor 31 (FIG. 3) of the thickness measuring unit 9 causes the storing unit 11 to store wafers W in order of thickness of the wafers W, thereby to rearrange the plurality of wafers W in order of thickness.

As shown in FIG. 9, a wafer thinning apparatus 7A includes a support table 105 for receiving cassettes C each storing a plurality of wafers W rearranged in order of thickness (with edge protection jigs 33 attached), a transfer arm 107 movable along the support table 105, a treating station 115 having a thinning unit 109, a rinsing unit 111 and a drying unit 113 arranged in order from the end remote from the transfer arm 107, a transport arm 117 movable along the treating station 115, and an intermediate arm 119 disposed between the transfer arm 107 and transport arm 117. A temporary support 121 is disposed adjacent the intermediate arm 119 for receiving a cassette C placed thereon with wafers C in a vertical position. The transfer arm 107 transports cassettes C between the support table 105 and temporary support 121. The intermediate arm 119 transports wafers W between the cassette C on the temporary support 121 and the transport arm 117. The thinning unit 109 has a treating tank 123 for storing a heated caustic potash (KOH) solution as a treating solution. The rinsing unit 111 has a rinsing tank 125 for storing heated deionized water. The drying unit 113 has a drying chamber 127 for drying and removing droplets from the wafers W cleaned with the deionized water. Further, the treating units 109, 111 and 113 have treatment arms 129, 131 and 133 vertically movable between positions above the tanks or chamber and positions inside the tanks or chamber, respectively. The transport arm 117 also transfers a plurality of wafers W as a batch between the treatment arms 129, 131 and 133.

The transfer arm 107, transport arm 117 and intermediate arm 119 correspond to the transport mechanism in this invention.

The above wafer thinning apparatus 7A has a control system constructed as shown in FIG. 10.

A control unit 135 performs an overall control of the transfer arm 107, transport arm 117, intermediate arm 119 and treating station 115. The control items include, for example, transfer of cassettes C by the transfer arm 107, movement control of the intermediate arm 119 and transport arm 117, transfer control of wafers W between the intermediate arm 119 and transport arm 117, lift control of the treatment arms 129, 131 and 133, and transfer control of wafers C between the treatment arms 129, 131 and 133 and transport arm 117.

The control unit 135 has a memory 137 connected thereto. The memory 137 stores treatment information including a “target thickness”, “thicknesses” of the wafers W, and an “etching rate” which is a treating rate of the treating solution. The control unit 135 causes the intermediate arm 119 to take the thickest wafer W out of the cassette C, and then transfers the wafer W to the treatment arm 129 through the transport arm 117. The control unit 135 also determines from the treatment information an immersion time for the wafer W held by the treatment arm 129. The next thickest wafer W is transported to the treatment arm 129, and is immersed along with the preceding wafer W in the treating solution stored in the treating tank 123. This treatment is performed for all the wafers W in the cassette C. The treatment arm 129 is raised to withdraw all the wafers W from the treating tank 123 when the wafer W first put to the treatment has reached the target thickness. The wafers W are moved to the rinsing tank 125 and to the drying chamber 127. The control unit 135 determines time intervals for adding the wafers W according to differences in thickness between adjoining wafers W, for example.

According to the foregoing wafer treating system 1A, the thickness measuring unit 9 of the rearranging apparatus 3A measures the thicknesses of a plurality of wafers W, and the storing unit 11 stores the wafers W in order of thickness in a cassette C. After the edge protection jig attaching apparatus 5 attaches an edge protection jig 33 to each wafer W, the control unit 135 of the wafer thinning apparatus 7A operates the transfer arm 107, transport arm 117 and intermediate arm 119 to transport the wafers W from the cassette C on the support table 105 to the treating tank 123, in the order of thickness from thickest to thinnest, to subject each wafer W to the treatment by the treating solution, and to withdraw all the wafers W upon completion of the treatment. The thicknesses of the plurality of wafers W are measured beforehand, and stored in the cassette C in order of thickness. The wafers W are immersed in the treating solution, successively, starting with the thickest wafer W, thereby changing the immersion time for each wafer W. This procedure can absorb the variations in thickness among the plurality of wafers W. Therefore, the thinning treatment with the treating solution chemically etching the plurality of wafers W can provide reduced variations in finishing thickness of the plurality of wafers W. Subsequently, the edge protection jig attaching and detaching apparatus 5 releases the edge protection jig from each wafer W. It is thus possible to thin only the part within the treatment circle of each wafer W, leaving the predetermined width of the treatment surface intact. The strength of wafers W is maintained after the thinning treatment. As a result, the wafers W can be handled with ease after the thinning treatment.

This invention is not limited to the foregoing embodiments, but may be modified as follows:

(1) In each of Embodiments 1 and 2 described above, the wafer thinning apparatus 7 or 7A includes the rinsing unit 85 or 111 and drying unit 87 or 113 as well. These units may be included in a separate apparatus, and the wafer thinning apparatus 7 or 7A may include only the thinning unit 83 or 109.

(2) Each of Embodiments 1 and 2 treats wafers W with the edge protection jigs 33 attached thereto by suction. These edge protection jigs 33 may be replaced by edge protection jigs having a mechanical lock mechanism.

(3) In each of Embodiments 1 and 2, the edge protection jig attaching and detaching apparatus 5 has been described as an example of apparatus for attaching and releasing the edge protection jigs. Where an extra installation area is available, this apparatus may be provided separately from the treating system.

(4) In each of Embodiments 1 and 2, the thinning treatment is carried out using a solution of caustic potash (KOH). The thinning treatment may be carried out with other treating solutions.

(5) In each of Embodiments 1 and 2, the thickness measuring unit 9 is the optical type. Instead, this unit may be the capacitance type, pneumatic type or laser type, for example.

This invention may be embodied in other specific forms without departing from the spirit or essential attributes thereof and, accordingly, reference should be made to the appended claims, rather than to the foregoing specification, as indicating the scope of the invention.

What is claimed is:

1. A wafer thinning method for treating wafers each having at least a circuit-forming surface thereof protected, by immersing the wafers in a treating solution, comprising the steps of:
sorting the wafers into groups according to predetermined ranges of thickness;
storing the wafers sorted into the groups in containers; a plurality of wafers in each of the groups being stored in one container;
transporting the containers successively to a treating tank storing the treating solution, and determining an immersion time for each group from a target thickness of the wafers, an average thickness in each group, and a treating rate by the treating solution; and
immersing the containers in the treating tank, with the immersion time changed for each group, such that the immersion time is made the longer for the groups having the thicker wafers.

2. The method according to claim 1, wherein a rinsing tank is provided for storing a rinsing liquid and receiving said containers, the method further comprising a rinsing step for transporting the containers withdrawn from said treating tank to said rinsing tank for rinsing treatment after the immersing step.

3. An method according to claim 2, wherein a drying unit is provided for receiving said containers to dry the wafers, the method further comprising a drying step for transporting the containers withdrawn from said rinsing tank to said drying unit for drying treatment after the rinsing step.
